(19) United States
(12) Patent Application Publication
(10) Pub. No.: US 2014/0138133 A1
(43) Pub. Date: May 22, 2014

(54) Transparent Electrode Comprising Electrode Line of High-Viscosity Conductive Nano Ink Composition and Touch Sensor, Transparent Heater and Electromagnetic Wave Shielding Material Using the Transparent Electrode

(71) Applicant: Enjet Co., Ltd., Gyeonggi-do (KR)

(72) Inventor: Do-Young Byun, Seoul (KR)

(73) Assignee: Enjet Co., Ltd., Gyeonggi-do (KR)

(21) Appl. No.: 14/083,503

(22) Filed: Nov. 19, 2013

(30) Foreign Application Priority Data
Nov. 19, 2012 (KR) 1020120130981

(51) Int. Cl. H05K 1/09; H05K 1/02

(52) U.S. Cl. CPC H05K 1/097; H05K 1/0274
USPC 174/257

(57) ABSTRACT

Provided herein is a transparent electrode comprising: a substrate; and an electrode pattern where a plurality of electrode lines are patterned in a mesh format on the substrate, wherein the width each electrode line is in the range of 0.1 to 15 μm, and the aspect ratio of each electrode line is in the range of 1:0.1 to 1:1, and each electrode line is made of a conductive nano structure, and a high viscosity conductive nano ink composition comprising a high molecular compound having a molecular weight between 50,000 and 1,000,000.

### CROSS-REFERENCE TO RELATED APPLICATIONS

This application claims the benefit of priority under 35 U.S.C. §119(a) of Korean Patent Applications No. 10-2012-0130981, filed on Nov. 19, 2012, in the Korean Intellectual Property Office, the entire disclosure of which is incorporated herein by reference for all purposes.

### BACKGROUND

1. Field

The following description relates to a transparent electrode comprising electrode lines made of high-viscosity conductive nano ink composition, and a touch sensor, transparent heater and electromagnetic wave shielding material using the transparent electrode, for example, to a transparent electrode comprising electrode lines with the line width and height capable of providing visibility, transparency, and optical characteristics, the electrode lines made of a high-viscosity conductive nano ink composition that is a mixture of a conductive nano structure and a high-molecular compound, thus having excellent properties due to the high-molecular compound preventing oxidization of the conductive nanostructure, and a touch sensor, transparent heater, and electromagnetic wave shielding material using the transparent electrode,

2. Description of Related Art

Transparent electrode plastic and transparent electrode glass are used not only in conventional displays such as LCDs or PDPs, but also in touch panels, OLED flexible displays, and organic solar cell processes that have recently grown significantly. ITO (Indium Tin Oxide) electrodes manufactured in sputtering methods are most frequently used transparent electrodes in these applications. This is because, with ITO electrodes, it is easy to form thin films, provide excellent light transmission, and low electrical resistance. However, problems are emerging such as high material costs due to the price rise of indium which is the main material, market instability and expected depletion of indium, degradation of devices due to the diffusion of indium, high reducibility under hydrogen plasma conditions, and bending instability such as cracks in flexible substrates etc. Especially, since an ITP transparent thin film is manufactured through a sputtering method under a high temperature vacuum condition, there are many problems in manufacturing large size thin films which require a continuous process. Developing a transparent electrode having optimal properties on a plastic substrate to be applied to flexible electronic devices has to be preceded. Conventional ITO had problems such as the process and substrate being deformed due to the difference of thermal expansion coefficient between an ITO electrode and plastic substrate, and the changing sheet resistance due to electrode destruction caused by bending of the electrode substrate etc.

In order to replace such ITO electrodes, organic transparent electrodes are being developed using organic material such as conductive high-molecular or carbone nanotube (CNT) and graphene. However, for an organic transparent electrode to have a sufficient electrical resistance, it must form a thick film, but this reduces the transparency, which is a problem.

Meanwhile, there is a technology of printing electrode ink having electrical conductivity in a grid form to use it as a transparent electrode, thereby resolving the problems of conventional transparent electrodes. Especially, it is possible to manufacture a transparent electrode having a high transparency and low electrical resistance by printing a metal type grid on a plastic or glass substrate. Gravure-offset printing and inkjet printing methods are used in manufacturing these transparent electrodes.

However, in the case of using the aforementioned printing methods, there occurs a problem of the difficult to manufacture a line having a width less than 10 μm, and the height of the electrode line being reduced (approximately 200 nm), thereby increasing the sheet resistance. Moreover, although a transparent electrode ought to have excellent optical characteristics, when these grid electrodes are applied to displays and touch panels etc., there occurs a problem of visibility of the grid being visible to people's eyes, and optical problems such as haze etc. Furthermore, according to the aforementioned printing methods, there occurs a problem of metal being directly exposed to air and thus oxidized.

Accordingly, there is a need to develop transparent electrodes capable of providing visibility, transparency, and optical characteristics but that can also be prevented from being oxidized.

### SUMMARY

Therefore, a purpose of the present disclosure is to resolve the aforementioned conventional problems, that is to provide a transparent electrode having excellent visibility, optical transmission rate and electrical characteristics, using a high viscosity conductive nano ink composition made of a conductive nano structure and high-molecular compound to form an electrode line, and further, to form an electrode pattern patterned in a mesh format, thereby embodying an electrode line of which the width is 10 μm or less, and the aspect rate is 1:0.1 to 1:1.

Another purpose of the present disclosure is to provide a transparent electrode capable of preventing oxidization of the conductive nano structure by including at least one of natural polymer compounds or synthetic polymer compounds in order to embody a high viscosity conductive nano ink composition.

Another purpose of the present disclosure is to provide a transparent electrode having excellent transparency and optical transmission rate by forming a mesh structure such that the distance between the electrode lines is 50 to 500 μm.

Another purpose of the present disclosure is to provide a transparent electrode printed in an electrohydrodynamic jet printing method, and self-aligned in the same direction as the direction where the conductive nano structure, especially the one-dimensional nano structure is printed, that is in the same direction as the pattern, so that the electrode line has a width of 10 μm or less.

Another purpose of the present disclosure is to provide a transparent electrode having excellent electrical characteristics and optical characteristics by coating an insulation layer of a substrate with a conductive material to provide a transparent electrode having enhanced electrical conductivity, and by coating the transparent electrode where an electrode pattern is printed with a conductive material. Furthermore, another purpose of the present disclosure is to provide a transparent electrode having even more excellent electrical characteristics and optical characteristics by forming a coating layer made of a conductive material on the substrate and the electrode pattern.

Lastly, another purpose of the present disclosure is to provide a touch sensor, transparent heater, and electromagnetic wave shielding material using the transparent electrode having excellent properties mentioned above.

In one general aspect, there is provided a transparent electrode comprising: a substrate; an electrode pattern where a plurality of electrode lines are patterned in a mesh format on the substrate, wherein the width each electrode line is in the range of 0.1 to 15 μm, and the aspect ratio of each electrode line is in the range of 1:0.1 to 1:1, and each electrode line is made of a conductive nano structure, and a high viscosity conductive nano ink composition comprising a high molecular compound having a molecular weight between 50,000 and 1,000,000.

In the general aspect of the transparent electrode, the conductive nano structure may be a nano particle or one-dimensional nano structure, and the one-dimensional nano structure may be at least one of a nano wire, nano rod, nano pipe, nano belt, and nano tube.

In the general aspect of the transparent electrode, the conductive nano structure may be a nano structure comprising at least one selected from among a group of Au, Ag, Al, Ni, Zn, Cu, Si, and Ti, or carbon nano tube, or a combination thereof.

In the general aspect of the transparent electrode, the high molecular compound may be at least one of a natural high molecular compound or synthetic high molecular compound.

In the general aspect of the transparent electrode, the natural high molecular compound may be at least one of chitosan, gelatin, collagen, elastin, hyaluronic acid, cellulose, silk fibroin, phospholipids, and fibrinogen, and the synthetic high molecular compound may be at least one of PLGA(Poly(lactic-co-glycolic acid)), PLA(Poly(lactic acid)), PHBV(Poly(3-hydroxybutyrate-hydroxyvalerate), PDO(Polydioxanone), PGA(Polyglycolic acid), PLCL(Poly(lactide-caprolactone)), PCL(Poly(e-caprolactone)), PLLA(Poly-L-lactic acid), PEUU(Poly(ether Urethane Urea)), Cellulose acetate, PEO(Polyethylene oxide), EVOH(Poly(Ethylene Vinyl Alcohol), PVA(Polyvinyl alcohol), PEG(Polyethylene glycol) and PVP(Polyvinylpyrrolidone).

In the general aspect of the transparent electrode, the plurality of electrode lines may be patterned in a distance of 50 to 500 μm from one another,

In the general aspect of the transparent electrode, the conductive nano ink composition may comprise the conductive nano structure coated with the high molecular compound.

In the general aspect of the transparent electrode, the plurality of electrode lines may be printed on the substrate in an electrohydrodynamic jet printing method, and the one-dimensional nano structure may be self-aligned in the same direction as the direction the electrode lines are printed.

In the general aspect of the transparent electrode, the substrate may be coated with carbon nano tune, graphene, or PEDOT, and the transparent electrode may further comprise a coating layer comprising carbon nano tune, graphene, or PEDOT.

In another general aspect, there is provided a touch sensor, transparent heater, and electromagnetic wave shielding material using the aforementioned transparent electrode.

According to the present disclosure, it is possible to embody an electrode line having a narrow width by forming a transparent electrode pattern with an electrode line made of a high-viscosity nano ink composition where a conductive nano structure and a high-molecular compound having a molecular weight of 50,000 to 1,000,000 are mixed, thereby providing a transparent electrode having excellent visibility, and by forming the electrode line having a high height, it is possible to improve the electrical conductivity of the transparent electrode.

Furthermore, according to the present disclosure, it is possible to provide a transparent electrode having excellent properties by coating the conductive nano structure with the high-molecular compound inside the conductive nano ink composition so as to prevent oxidization of the conductive nano structure.

Furthermore, according to the present disclosure, it is possible to provide a transparent electrode printed in an electrohydrodynamic jet printing method, patterned in a simple method without having to repeat the deposition and etching processes, and self-aligned in the same direction as the printing direction, so that the electrode line has a narrow width of 10 μm or less.

Moreover, according to the present disclosure, it is possible to provide a transparent electrode where as a conductive material such as carbon nano tube, graphene, and PEDOT is coated on the substrate patterned with a conductive nano ink composition, the electrical conductivity improves, and it is also possible to coat the transparent electrode where a conductive nano ink composition is patterned, with a conductive material, thereby providing a transparent electrode that maximizes the aforementioned effect.

Furthermore, according to the present disclosure, it is possible to provide a touch sensor, transparent heater, and electromagnetic wave shielding material having excellent visibility, transparent, and optical characteristics using the transparent electrode.

### BRIEF DESCRIPTION OF THE DRAWINGS

Throughout the drawings and the detailed description, unless otherwise described, the same drawing reference numerals will be understood to refer to the same elements, features, and structures. The relative size and depiction of these elements may be exaggerated for clarity, illustrating, and convenience.

FIG. 1 illustrates an SEM photograph (a) of an electrode pattern where a nano ink composition is used according to the present disclosure; and an SEM photograph (b) of an electrode pattern where a conductive nano ink composition is used that does not include a high-molecular compound of the present disclosure.

FIG. 2 is a mimetic diagram of an electrode line comprising a nano structure coated with a high-molecular compound according to the present disclosure.

FIG. 3 is a graph illustrating the transmittance according to the coating thickness of a high-molecular compound forming an electrode line of a transparent electrode according to the present disclosure.

FIG. 4 is illustrates a mimetic diagram of a patterning of a conductive nano ink composition in an electrohydrodynamic jet printing method and a mimetic diagram of a transparent electrode patterned in a mesh structure.

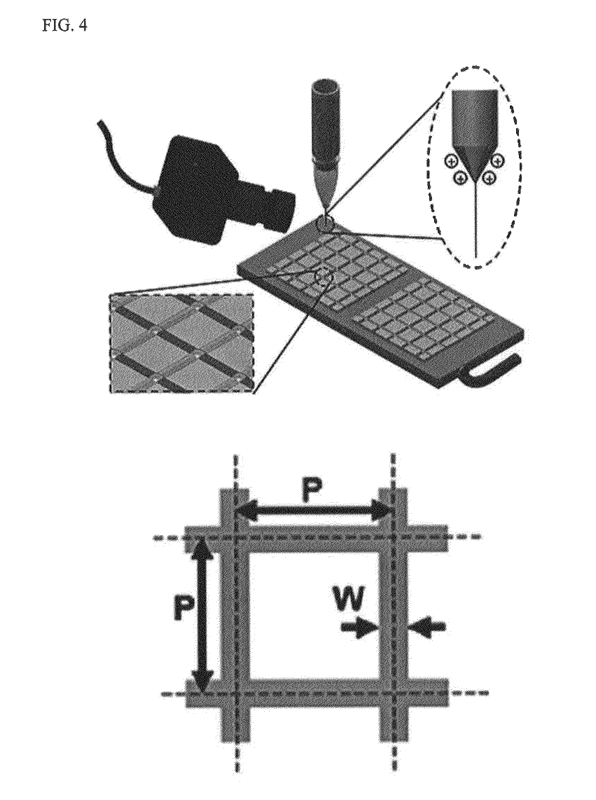

FIG. 5 is a graph illustrating the sheet resistance and transmittance according to the distance between electrode lines of a transparent electrode where a conductive nano ink composition is used.

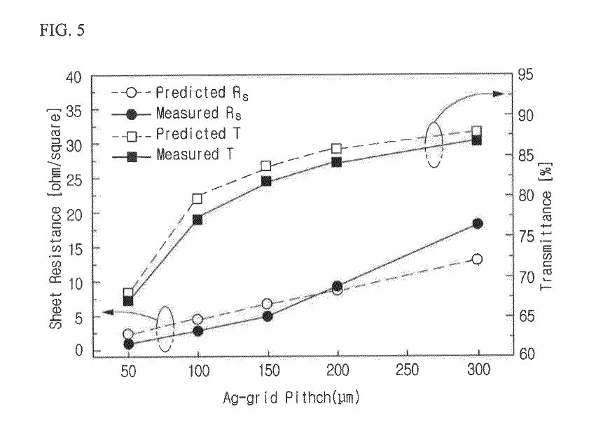

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

A transparent electrode of the present disclosure consists of a substrate and an electrode pattern, the electrode pattern being a plurality of electrode lines patterned in a mesh format on or above the substrate. The mesh structure may be of a square structure that is a general grid structure, diamond structure or honey comb structure etc., and there is no limitation to the shape of the mesh structure depending on the use of the transparent electrode.

In the case of forming an electrode line using a conductive nano ink composition, it is possible to embody an electrode line to have a width of 0.01 to 15 μm, while maintaining the constant viscosity of 1,000 to 100,000 cP. More desirably, the width may be 0.1 to 10 μm, and most desirably 0.5 to 5 μm. If the width exceeds 15 μm, the pattern of mesh structure could be recognized from outside, significantly deteriorating the properties of the transparent electrode.

Furthermore, by using a high-viscosity conductive nano ink composition, it is possible to embody an aspect ratio (width: height) of 1:0.1 to 1:1 , desirably 1:0.1 to 0.5, and more desirably 1:0.15. In order to improve the electrical conductivity, the cross-sectional area of the electrode line must be big. Therefore, when the aspect ratio is in the aforementioned range, the cross-sectional area will increase, reducing the sheet resistance, and thus making it possible to provide a transparent electrode with excellent electrical conductivity. A conventional electrode line having a width of 10 μm would be 200 μm high, but according to the present disclosure, by the conductive nano ink composition, it is possible to embody an electrode line to be approximately 1.5 μm high in the case where the width is 10 μm. Thus, the height of the electrode line would become approximately 750 times bigger, significantly improving the electrical conductivity.

The conductive nano ink composition of the present disclosure is a composition used for an electrode line of a transparent electrode and enabling the aforementioned widths and aspect ratios. This is a jetting solution used in an electrohydrodynamic jet printing method, and is made of a conductive nano structure and high-molecular compound.

The conductive nano structure has excellent electrical, mechanical, and thermal characteristics, and thus may be used as a base material of a conductive nano ink composition. The conductive nano structure may desirably be of nano particles or of one-dimensional structure such as nano wire, nano rod, nano pipe, nano belt, and nano tube, or a combination of nano particles and the aforementioned one-dimensional nano structure.

Furthermore, the conductive nano structure may desirably be a nano structure consisting of at least one selected from among a group of gold(Au), silver(Ag), aluminium(Al), nickel(Ni), zinc(Zn), copper(Cu), silicon(Si) or titanium(Ti), or carbon nano tube, or a combination thereof. Especially, silver nano wire that can be easily self-aligned is most effective for a transparent electrode. This will he explained in more detail hereinbelow.

A high-molecular compound is for adjusting the viscosity and optical characteristics of a conductive nano ink composition. It is capable of adjusting the viscosity of an ink composition, and thus may not only improve the jetting performance during the patterning but also prevent oxidization of the conductive nano structure, providing excellent optical characteristics and properties.

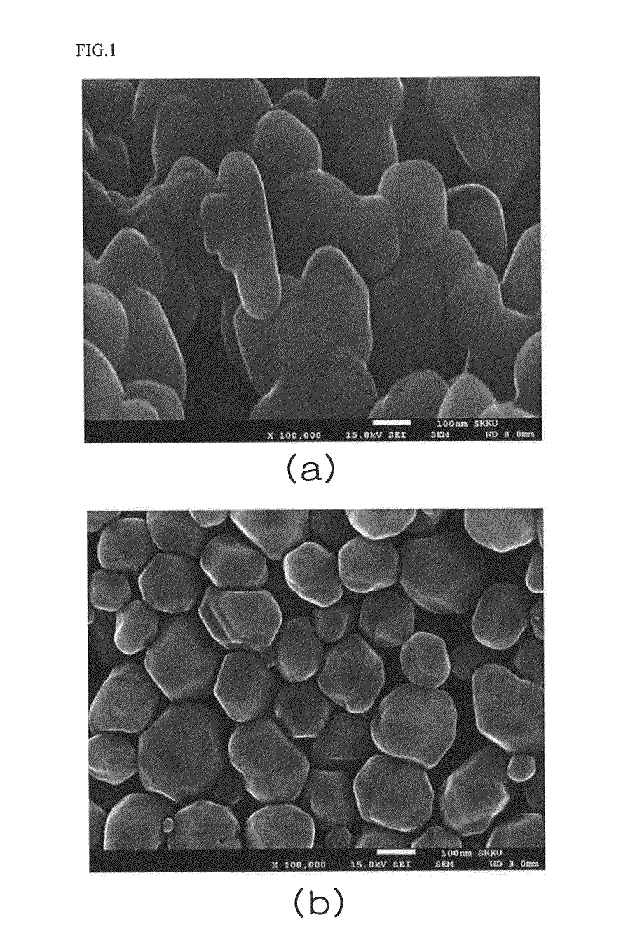

As can be seen in FIG. 1(a), the conductive nano ink composition comprises a conductive nano structure coated with a high-molecular compound, preventing the conductive nano structure from being exposed to air and oxidization.

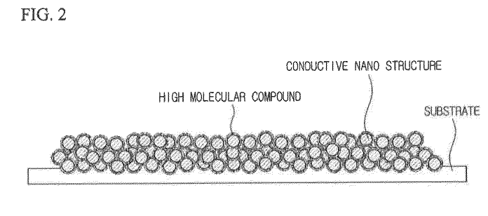

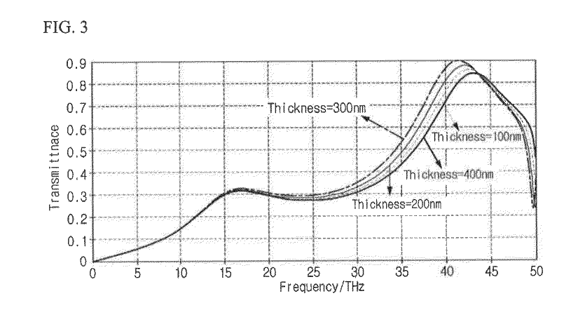

As in the mimetic diagram of FIG. 2, an electrode line has a structure where a coating film of a high-molecular compound is deposited on or above the conductive nano structure. Furthermore, in the structure of FIG. 2, as can he seen in the graph of FIG. 3, the optical transmission improves as the thickness of the high-molecular compound coating increases from 100 nm to 300 nm, but when the thickness of the coating is 400 nm, the optical transmission decreases. This doesn't mean that the optical transmission always decreases when the thickness of the coating of the high-molecular compound increases, but that the transmission increases and the electrical conductivity is maintained the same up to a certain thickness.

The molecular weight of the high molecular compound is desirably 50,000 to 1,000,000, more desirably 100,000 to 500,000. The compound may be a natural high molecular compound or a synthetic high molecular compound. There is no limitation to the type of the high molecular compound. If the molecular weight of the high-molecular compound is 50,000 or below, when forming an electrode pattern using a conductive nano ink composition, the width of the electrode line increases and the electrode line becomes recognizable from outside, decreasing the reliability as a transparent electrode, and easily oxidizing the transparent electrode. If the molecular weight of the high molecular compound exceeds 1,000,000, there is a limitation in dissolving the conductive nano structure in a solvent when manufacturing a nano ink composition, thereby significantly decreasing the electrical conductivity.

Herein, according to an exemplary embodiment, the natural high-molecular compound is desirably at least one of chitosan, gelatin, collagen, elastin, hyaluronic acid, cellulose, silk fibroin, phospholipids, and fibrinogen, and the synthetic high molecular compound is desirably at least one of PLGA(Poly(lactic-co-glycolic acid)), PLA(Poly(lactic acid)), PHBV(Poly(3-hydroxybutyrate-hydroxyvalerate), PDO(Polydioxanone), PGA(Polyglycolic acid), PLCL(Poly(lactide-caprolactone)), PCL(Poly(e-caprolactone)), PLLA(Poly-L-lactic acid), PEUU(Poly(ether Urethane Urea)), Cellulose acetate), PEO(Polyethylene oxide), EVOH(Poly(Ethylene Vinyl Alcohol), PVA(Polyvinyl alcohol), PEG(Polyethylene glycol), and PVP(Polyvinylpyrrolidone). Depending on the type of the conductive nano structure, it is possible combine a natural high-molecular compound and a synthetic high-molecular compound. In the present disclosure, in the case of embodying an ink composition with a conductive nano structure, it is the easiest to adjust the viscosity when using PEG or PEO as the high-molecular compound.

To 100 parts by weight of the conductive nano structure, the high-molecular compound may desirably be 0.05 to 15 parts by weight, more desirably 0.1 to 10 parts by weight. When the high molecular compound is less than 0.05 parts by weight, in the case of forming an electrode line in the electrohydrodynamic jet printing method, jetting gets unstable and multi-jets may be discharged, and thus it becomes not possible to perform the patterning, the electrode line gets discontinuous, and further, if the high-molecular compound exceeds 15 parts by weight, the electrical characteristics deteriorates significantly.

In addition, the conductive nano ink composition of the present disclosure desirably has electrically leaky dielectric characteristics of 10⁻¹⁰ s/m to 1.0⁻¹ s/m, more desirably 10⁻¹⁰ s/m to 10⁻³ s/m. That is, the properties of the electrode line may improve when the conductive nano ink composition has an electrical conductivity between that of benzene which is very low and that of mercury which is very high.

An electrode line made of such a conductive nano ink composition may have a mesh structure patterned by a distance of desirably 50 to 500 μm, and more desirably 100 to 200 μm. Otherwise, the transparency and electrical conductivity will be affected.

As illustrated in FIG. 2, the conductive nano ink composition forms a pattern, and in the grid-type electrode illustrated in FIG. 2, p represents the distance between electrode lines, w represents the width of the electrode lines. With the distance between electrode lines, p, and w, the width of the electrode lines, it is possible to denote how much the electrode of the mesh structure blocks the proceeding direction of light or electromagnetic waves on a two-dimensional plane with fill factor (FF). The FF value is as shown in the [Mathematical Formula 1] below.

$$FF = \frac{( pSw ) + [ ( p - w ) Sw ]}{{p}^{2}} \qquad [ Mathematical Formula 1 ]$$

Using FF, the sheet resistance, R_{s,Ag grid} and transmittance, T_{Ag grid} are as in [Mathematical Formula 2] and [Mathematical Formula 3] below. This is an equation of the sheet resistance and transmittance when an electrode of mesh structure is formed using Ag. ρ_{Ag grid} is the electric resistance of Ag, t_{Ag grid} is the thickness of the grid electrode, ξ is the constant number for calculating the sheet resistance, and T_{B} is the original transmittance of the substrate.

$$\begin{matrix}{R}_{s , Aggrid} = ξ \frac{{ρ}_{Aggrid}}{{t}_{Aggrid}} \frac{1}{FF} & [ Mathematical Formula 2 ] \\ {T}_{Aggrid} = {T}_{B} S ( 1 - FF ) & [ Mathematical Formula 3 ]\end{matrix}$$

As can be seen from the aforementioned mathematical formulas 2 and 3, the smaller the FF, it becomes possible to manufacture a transparent electrode with excellent performance of high transmittance and low sheet resistance. Furthermore, as can be seen from FIG. 3, the smaller the distance, the lower the transparency and the sheet resistance, enhancing electrical characteristics.

Conductive nano structures such as nanowire and nanotube are arranged indiscriminately without any particular directing point when there is no stimulating element of surrounding environment, and thus there is difficulty in performing a patterning. Accordingly, when embodying a conductive nano ink composition as in the present disclosure and patterning an electrode line in the electrohydrodynamic jet printing method, it is possible to form an electric field to generate an electric field between the nozzle and substrate, thereby aligning the conductive nano structure in the direction parallel to the printing direction by the potential difference. Consequently, the nano material on the substrate is aligned along the printing direction, that is the patterning direction, which enables forming a pattern of electrode lines having a narrow width of below 10 μm. This becomes more distinct when the conductive nano structure is a one-dimensional nano structure.

A more desirable exemplary embodiment of the present disclosure may further comprise a coating layer deposited on or above a substrate, or on the substrate where electrode lines are patterned. The coating layer may be made of carbon nanotube, graphene, or PEDOT, so as to reinforce the adhesion between the substrate and electrode lines, while reducing the surface roughness, thereby providing a transparent electrode having excellent properties and improved electrical conductivity.

A most desirable exemplary embodiment of the present disclosure may further comprise a coating layer made of conductive materials, that is, nanotube, graphene, or PEDOT, the coating layer being deposited on the substrate, yet another coating layer made of conductive materials deposited on the substrate pattern. This may further improve the electrical conductivity of the conductive nano ink composition.

Furthermore, it is desirable that a touch sensor, transparent heater or electromagnetic wave shielding material of the present disclosure use the aforementioned mesh-format transparent electrode. The transparent electrode of the present disclosure may he utilized as a touch sensor, and may thus be applied in various fields including display etc. In addition, the aforementioned transparent electrode may be applied to transparent substrates such as glass in buildings or housings, glass in automobiles, and goggles etc., to perform the role of preventing fogging, melting of condensed water, and melting of snow. Furthermore, the mesh-format transparent electrode may perform the role of an electromagnetic wave shielding material for displays, smart phones, missiles, airplanes etc. Furthermore, since embodying a transparent electrode by performing the electrohydrodynamic jet printing method using a conductive nano ink composition does not require a depositing or etching process, electrode patterning can be easily performed on three-dimensional surfaces as well, and thus enables embodying a three-dimensional touch sensor, three-dimensional transparent heater, and three-dimensional electromagnetic wave shielding material. Especially, it is possible to form an electromagnetic wave shielding surface by directly patterning the surface of a missile or airplane etc. in the electrohydrodynamic jet printing method.

A number of examples have been described above. Nevertheless, it will be understood that various modifications may be made. For example, suitable results may be achieved if the described techniques are performed in a different order and/or if components in a described system, architecture, device, or circuit are combined in a different matter and/or replaced or supplemented by other components or their equivalents. Accordingly, other implementations are within the scope of the following claims.

What is claimed is:

1. A transparent electrode comprising:
a substrate; and
an electrode pattern where a plurality of electrode lines are patterned in a mesh format on the substrate,
wherein the width each electrode line is in the range of 0.1 to 15 μm, and the aspect ratio of each electrode line is in the range of 1:0.1 to 1:1, and
each electrode line is made of a conductive nano structure, and a high viscosity conductive nano ink composition comprising a high molecular compound having a molecular weight between 50,000 and 1,000,000.

2. The transparent electrode according to claim 1,
wherein the conductive nano structure is a nano particle or one-dimensional nano structure.

3. The transparent electrode according to claim 2,
wherein the one-dimensional nano structure is at least one of a nano wire, nano rod, nano pipe, nano belt, and nano tube.

4. The transparent electrode according to claim 1,
wherein the conductive nano structure is a nano structure comprising at least one selected from among a group of Au, Ag, Al, Ni, Zn, Cu, Si, and Ti, or carbon nano tube, or a combination thereof.

5. The transparent electrode according to claim 1,
wherein the high molecular compound is at least one of a natural high molecular compound or synthetic high molecular compound.

6. The transparent electrode according to claim 5,
wherein the natural high molecular compound is at least one of chitosan, gelatin, collagen, elastin, hyaluronic acid, cellulose, silk fibroin, phospholipids, and fibrinogen.

7. The transparent electrode according to claim 5,
wherein the synthetic high molecular compound is at least one of PLGA(Poly(lactic-co-glycolic acid)), PLA(Poly(lactic acid)), PHBV(Poly(3-hydroxybutyrate-hydroxyvalerate), PDO(Polydioxanone), PGA(Polyglycolic acid), PLCL(Poly(lactide-caprolactone)), PCL(Poly(e-caprolactone)), PLLA(Poly-L-lactic acid), PEUU(Poly(ether Urethane Urea)), Cellulose acetate, PEO(Polyethylene oxide), EVOH(Poly(Ethylene Vinyl Alcohol), PVA(Polyvinyl alcohol), PEG(Polyethylene glycol) and PVP(Polyvinylpyrrolidone).

8. The transparent electrode according to claim 1,
wherein the plurality of electrode lines are patterned in a distance of 50 to 500 μm from one another.

9. The transparent electrode according to claim 1,
wherein the conductive nano ink composition comprises the conductive nano structure coated with the high molecular compound.

10. The transparent electrode according to claim 2,
wherein the plurality of electrode lines are printed on the substrate in an electrohydrodynamic jet printing method and the one-dimensional nano structure may be self-aligned in the same direction as the direction the electrode lines are printed.

11. The transparent electrode according to claim 1,
wherein the substrate is coated with carbon nano tune, graphene, or PEDOT.

12. The transparent electrode according to claim 1,
wherein the transparent electrode further comprises a coating layer comprising carbon nano tune, graphene, or PEDOT.

13. A touch sensor using a transparent electrode according to claim 1.

14. A transparent heater using a transparent electrode according to claim 1.

15. An electromagnetic wave shielding material using a transparent electrode according to claim 1.
